(19) United States
(12) Patent Application Publication
(10) Pub. No.: US 2026/0199928 A1
(43) Pub. Date: Jul. 16, 2026

(54) DISPENSING APPARATUS, DISPENSING METHOD, AND ELECTRONIC DEVICE

(71) Applicant: Samsung Display Co., LTD., Yongin-si, Gyeonggi-do (KR)

(72) Inventor: CHANHAE HWANG, Yongin-si (KR)

(21) Appl. No.: 19/287,018

(22) Filed: Jul. 31, 2025

(30) Foreign Application Priority Data
Jan. 14, 2025 (KR) 10-2025-0005516

(51) Int. Cl. B05C 5/02; B05B 1/02; H10H 29/30; H10K 59/40

(52) U.S. Cl. CPC B05C 5/0291; B05B 1/02; H10H 29/30; H10K 59/40

(57) ABSTRACT

A dispensing apparatus includes a stage on which a substrate is seated, a dispensing head positioned above the stage, including a head electrode to which a first voltage is applied to electrically charge a resin, and configured to discharge the charged resin through a nozzle onto the substrate in the form of dots, and a resin control electrode positioned between the dispensing head and the stage, where a second voltage having a same polarity as the first voltage is applied to the resin control electrode to control a position of the resin dot discharged from the nozzle.

This application claims priority to Korean Patent Application No. 10-2025-0005516, filed on January 14, 2025, and all the benefits accruing therefrom under 35 U.S.C. §119, the content of which in its entirety is herein incorporated by reference.

### BACKGROUND

### Field

Embodiments relate to a dispensing apparatus, a dispensing method, and an electronic device. More particularly, embodiments relate to a resin dispensing apparatus, a dispensing method using the resin dispensing apparatus, and an electronic device manufactured using the resin dispensing apparatus.

### Description of the Related Art

Flat panel display devices are replacing cathode ray tube display devices as display devices due to their lightweight and thin characteristics. As representative examples of such flat panel display devices, there are liquid crystal display devices and organic light emitting diode display devices.

A resin layer may be formed to an edge of the display device to perform various functions, such as improving the strength of the display device, preventing moisture penetration from the outside, preventing light leakage from the side of the display device, or the like.

### SUMMARY

Embodiments provide a dispensing apparatus with improved discharge accuracy.

Embodiments also provide a dispensing method with improved discharge accuracy.

Embodiments also provide an electronic device manufactured using the dispensing apparatus.

Additional features of the invention will be set forth in the description which follows, and in part will be apparent from the description, or may be learned by practice of the invention.

A dispensing apparatus according to an embodiment includes a stage on which a substrate is seated, a dispensing head positioned above the stage, where the dispensing head includes a head electrode to which a first voltage is applied to electrically charge a resin, and the dispensing head discharges a charged resin through a nozzle thereof onto the substrate in the form of dots, and a resin control electrode positioned between the dispensing head and the stage, where a second voltage having a same polarity as the first voltage is applied to the resin control electrode to control a position of a resin dot discharged from the nozzle.

In an embodiment, in a plan view, the resin control electrode may have a ring shape in which an opening is defined at an inner portion thereof.

In an embodiment, the resin dot discharged from the nozzle of the dispensing head may pass through the opening of the resin control electrode and may be landed on the substrate.

In an embodiment, the dispensing apparatus may further include an electrode moving unit which moves the resin control electrode.

In an embodiment, the dispensing apparatus may further include a measuring unit which measures the position of the resin dot landed on the substrate, and a control unit which controls the electrode moving unit to adjust in real time a position of the resin control electrode relative to the dispensing head based on a measurement data received from the measuring unit.

In an embodiment, the dispensing apparatus may further include a head moving unit which moves the dispensing head relative to the stage.

In an embodiment, the resin control electrode may move together with the dispensing head when the dispensing head moves.

In an embodiment, the dispensing apparatus may further include a stage moving unit which moves the stage relative to the dispensing head.

In an embodiment, the resin control electrode may be provided in plurality. In such an embodiment, a plurality of resin control electrodes may include a first resin control electrode positioned below the dispensing head, where the second voltage is applied to the first resin control electrode, and a second resin control electrode positioned below the first resin control electrode, where a third voltage having the same polarity as the first voltage is applied to the second resin control electrode.

In an embodiment, in a plan view, each of the first resin control electrode and the second resin control electrode may have a ring shape in which an opening is defined at an inner portion thereof. In such an embodiment, a size of the opening defined in the second resin control electrode may be less than a size of the opening defined in the first resin control electrode.

In an embodiment, a magnitude of the second voltage may be different from a magnitude of the third voltage.

In an embodiment, the dispensing apparatus may further include a first electrode moving unit which moves the first resin control electrode, and a second electrode moving unit which moves the second resin control electrode.

In an embodiment, the dispensing head further may include a plate which forms a main body of the dispensing head and defines an outflow passage extending upward from the nozzle and an inflow passage communicating with the outflow passage, where the resin is introduced into the dispensing head through the inflow passage from a resin supply unit, and the head electrode may be close to the inflow passage.

In an embodiment, the head electrode directly may contact the resin in the inflow passage.

In an embodiment, each of the first voltage and the second voltage may be a positive voltage.

A dispensing method according to an embodiment includes electrically charging a resin passing through an inflow passage of a dispensing head, discharging a charged resin through a nozzle of the dispensing head onto a substrate in the form of dots, and controlling a landing position of a resin dot on the substrate, by adjusting a position of the dispensing head relative to a stage, on which the substrate is seated, or by adjusting a position of a resin control electrode, which is positioned between the dispensing head and the stage and is electrically charged with a same polarity as the charged resin, relative to the dispensing head.

In an embodiment, the method may further include, before the controlling the landing position of the resin dot, generating measurement data by measuring the landing position of the resin dot on the substrate. In such an embodiment, in the controlling the landing position of the resin dot, the position of the resin control electrode relative to the dispensing head may be adjusted in real time based on the measurement data.

In an embodiment, the method may further include, after the generating the measurement data, inspecting a landing state of the resin dot on the substrate by calculating an error between the landing position of the resin dot and a target position based on the measurement data. The step of controlling the landing position of the resin dot may include determining that resin dot is normally landed when the error is equal to or less than a first threshold value, adjusting a position of the resin control electrode relative to the dispensing head by moving the resin control electrode when the error is greater than the first threshold value and is equal to or less than a second threshold value, and adjusting a position of the dispensing head relative to the stage by moving the dispensing head or the stage when the error is greater than the second threshold value.

In an embodiment, the resin control electrode may move together with the dispensing head when the dispensing head moves.

An electronic device according to an embodiment includes a display device including a display panel which displays an image and a resin layer disposed on the display panel and formed by a dispensing apparatus, and a processor which provides an image data signal and an input control signal to the display panel. In such an embodiment, the dispensing apparatus includes a stage on which a substrate is seated, a dispensing head positioned above the stage, where the dispensing head includes a head electrode to which a first voltage is applied to electrically charge a resin, and the dispensing head discharges a charged resin through a nozzle thereof onto the substrate in the form of dots, and a resin control electrode positioned between the dispensing head and the stage, where a second voltage having a same polarity as the first voltage is applied to the resin control electrode to control a position of the resin dot discharged from the nozzle.

The dispensing apparatus according to embodiments may include the dispensing head including the head electrode for electrically charging the resin, which is a coating material, and the resin control electrode to which a voltage having a same polarity as the polarity of the charged resin is applied. The dispensing head may discharge the charged resin in the form of dots. The resin dot discharged from the dispensing head may pass through the opening of the resin control electrode, and may be landed on the substrate. The dispensing apparatus may control in real time the path of the resin dot, by adjusting in real time the position of the resin control electrode relative to the dispensing head, based on a landing state of the resin dot, so that the resin dot may land on a target position on the substrate. Accordingly, the discharge accuracy of the dispensing apparatus may be improved.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the invention.

FIG. 1 is a schematic diagram illustrating a dispensing apparatus according to an embodiment.

FIG. 2 is a plan view illustrating a resin control electrode of FIG. 1.

FIG. 3 is a schematic diagram illustrating a dispensing apparatus according to an embodiment.

FIG. 4 is a schematic diagram illustrating a dispensing apparatus according to an embodiment.

FIG. 5 is a flowchart illustrating a dispensing method according to an embodiment.

FIG. 6 is a perspective view illustrating a display device according to an embodiment.

FIG. 7 is a cross-sectional view of the display device of FIG. 6.

FIG. 8 is a block diagram illustrating an electronic device according to an embodiment.

FIG. 9 is a schematic diagram illustrating an electronic device according to various embodiments.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

In the disclosure, various modifications can be made, various forms can be used, and specific embodiments will be illustrated in the drawings and described in detail in the text. However, this is not intended to limit the disclosure to a specific form disclosed, and it will be understood that all changes, equivalents, or substitutes which fall in the spirit and technical scope of the disclosure should be included.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will be understood that when an element is referred to as being “connected” or “coupled” to another element, it can be directly connected or coupled to the other element or intervening element(s) may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the specification, an x-axis, a y-axis, and a z-axis are not limited to three axes on an orthogonal coordinate system, but may be interpreted in a broad sense including the three axes. For example, the x-axis, the y-axis, and the z-axis may be perpendicular to one another, or may represent different directions that are not perpendicular to one another. Here, the direction of the x-axis may be referred to as x direction or x-axis direction, the direction of the y-axis may be referred to as y direction or y-axis direction, and the direction of the z-axis may be referred to as z direction or z-axis direction.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described in detail with reference to the accompanying drawings.

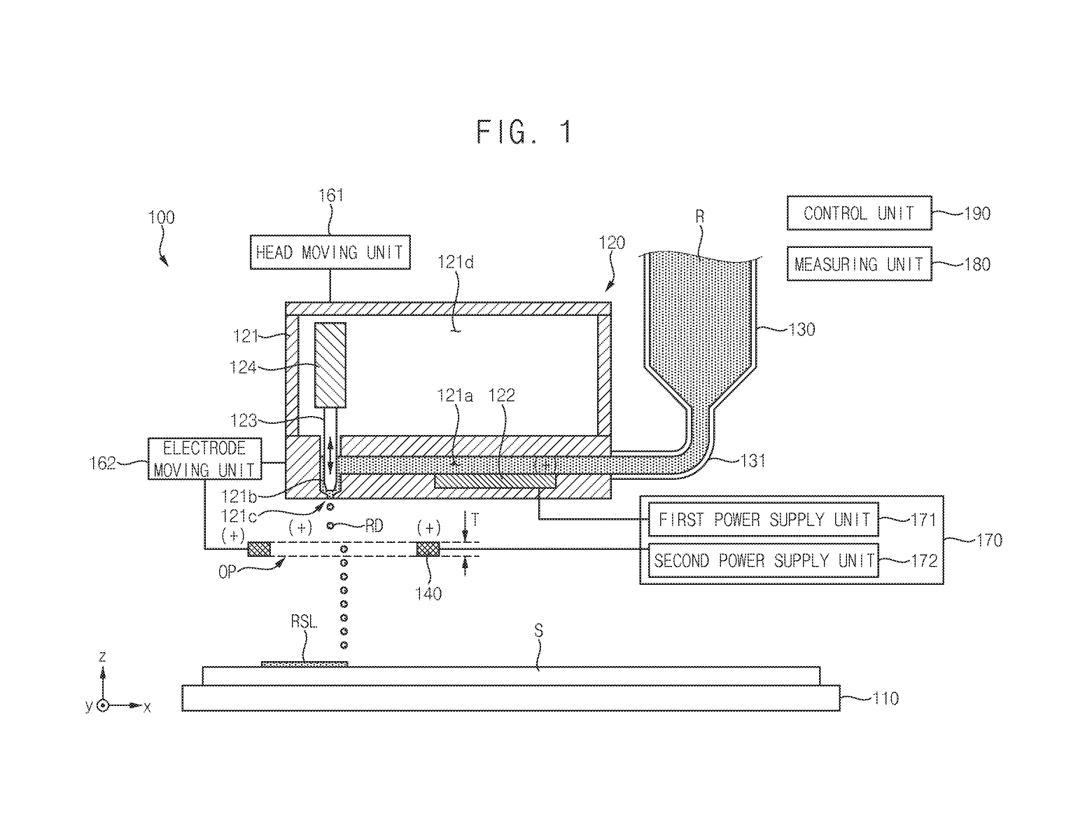

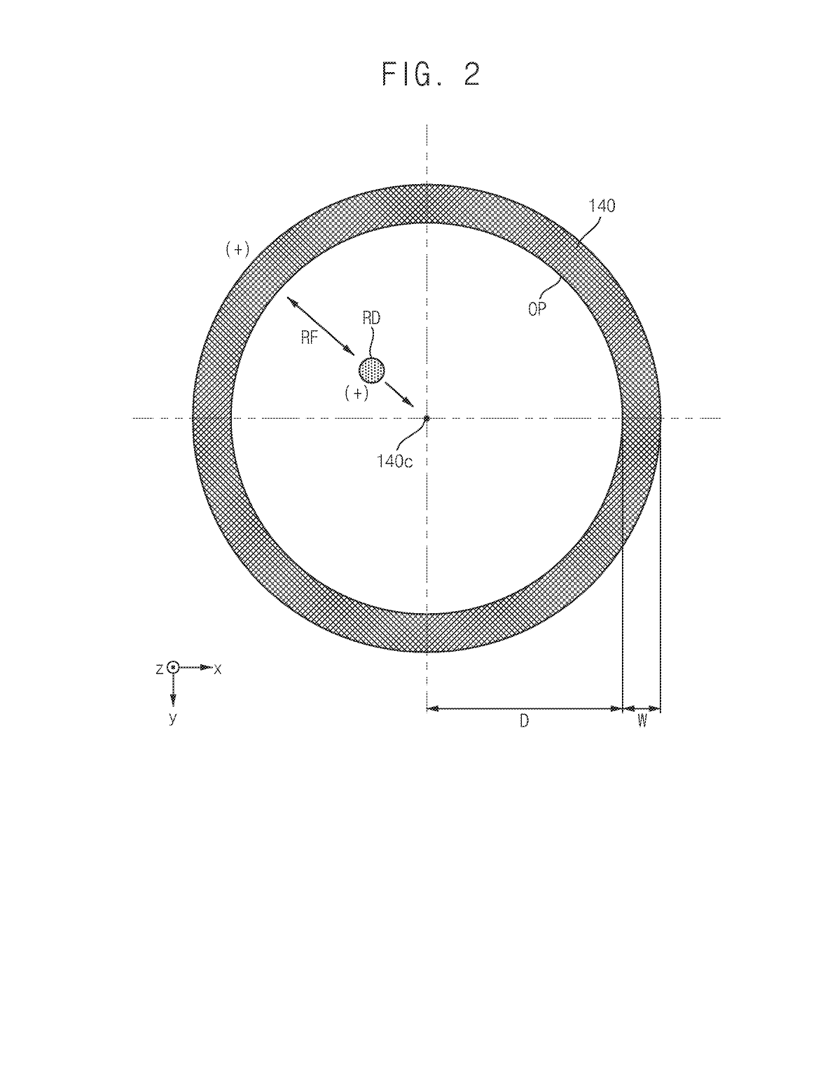

FIG. 1 is a schematic diagram illustrating a dispensing apparatus according to an embodiment. FIG. 2 is a plan view illustrating a resin control electrode of FIG. 1.

Referring to FIGS. 1 and 2, in an embodiment, a dispensing apparatus 100 may include a stage 110, a dispensing head 120, a resin supply unit 130, a resin control electrode 140, a head moving unit 161, an electrode moving unit 162, a power supply unit 170, a measuring unit 180, and a control unit (or controller) 190.

A substrate S may be seated on the stage 110. The substrate S may be seated on an upper surface of the stage 110. In an embodiment, for example, the upper surface of the stage 110 may be substantially parallel to a xy plane. In an embodiment, for example, the substrate S may be a display module or a substrate in an intermediate stage of manufacturing a display module, but the invention is not limited thereto.

The dispensing head 120 may be positioned in an upward direction (+z direction) from the stage 110 and the substrate S. The dispensing head 120 may discharge (or dispense) a coating material toward the substrate S in a downward direction (-z direction), which is the direction of gravity. In an embodiment, the dispensing apparatus 100 may be a resin dispensing apparatus that discharges (or dispenses) resin R. The dispensing head 120 may discharge the resin R through a nozzle 121c in the form of dots. That is, the resin R supplied from the resin supply unit 130 may be continuously or successively discharged toward the substrate S by the dispensing head 120 in the form of fine dots. Hereinafter, the resin R discharged in the form of dots from the nozzle 121c of the dispensing head 120 may be referred to as a resin dot RD.

In an embodiment, the dispensing head 120 may include a plate 121, a head electrode 122, a rod 123, and a rod driving unit 124.

The plate 121 may form a main body of the dispensing head 120. The plate 121 may define an inflow passage 121a, an outflow passage 121b, the nozzle 121c, and an accommodating space 121d. In an embodiment, the plate 121 may be provided by combining a plurality of plates (e.g., a nozzle plate, a passage plate, or the like).

The inflow passage 121a may be connected to the resin supply unit 130. The resin R, which is the coating material, may be stored in a storage space of the resin supply unit 130. The storage space of the resin supply unit 130 may be communicated with the inflow passage 121a of the dispensing head 120 through a pipe 131. Accordingly, the resin R stored in the resin supply unit 130 may be introduced into the inflow passage 121a of the dispensing head 120 through the pipe 131.

The head electrode 122 may be adjacent to the inflow passage 121a. The head electrode 122 may include a conductive material, such as a metal or an alloy. In an embodiment, for example, the head electrode 122 may include a highly conductive metal, such as copper, but this is merely an example and the invention is not limited thereto.

A first voltage may be applied to the head electrode 122 to electrically charge the resin R passing through the inflow passage 121a. In an embodiment, for example, the first voltage may be a positive voltage. The resin R passing through the inflow passage 121a may be positively charged by the head electrode 122. In an embodiment, for example, the magnitude (or voltage level) of the first voltage may be in a range of about 0.1 kilovolt(kV) to about 10 kV, but this is merely an example and the invention is not limited thereto.

In an embodiment, as illustrated in FIG. 1, the head electrode 122 may be configured to directly contact the resin R in the inflow passage 121a to electrically charge the resin R. In an embodiment, for example, the head electrode 122 may be formed to at least partially surround the inflow passage 121a, but this is merely an example and the invention is not limited thereto. In an embodiment, the head electrode 122 may be configured to further contact a lower portion of the outflow passage 121b and the nozzle 121c.

The outflow passage 121b may extend in the upward direction (+z direction) from the nozzle 121c, and may be communicated with the inflow passage 121a and the accommodating space 121d. In an embodiment, for example, the inflow passage 121a may be communicated with a middle portion of the outflow passage 121b, and may extend in one direction (e.g., +x direction) from the middle portion of the outflow passage 121b.

The nozzle 121c may be provided or defined at the lower portion of the outflow passage 121b. In an embodiment, for example, the nozzle 121c may be formed relatively small (e.g., to have a relatively small cross-sectional area) to discharge a micro-amount of the resin R and improve discharge accuracy. A diameter of the nozzle 121c may be less than a diameter of the outflow passage 121b. In an embodiment, for example, the diameter of the nozzle 121c may be in a range of about 10 micrometers to 100 micrometers, but this is merely an example and the invention is not limited thereto.

A portion of the lower portion of the outflow passage 121b (between the middle portion of the outflow passage 121b, which is communicated with the inflow passage 121a, and the nozzle 121c) may be filled with the resin R, which is introduced through the inflow passage 121a and is positively charged by the head electrode 122.

The accommodating space 121d may be communicated with an upper portion of the outflow passage 121b. The rod 123 and the rod driving unit 124 may be disposed in the accommodating space 121d.

The rod 123 may extend in the z-axis direction. A lower portion of the rod 123 may be inserted into the outflow passage 121b. An upper portion of the rod 123 may be connected to the rod driving unit 124. The rod 123 may be driven in the upward and downward directions (+z and –z directions) by the rod driving unit 124. As the rod 123 is driven in the upward and downward directions (+z and –z directions), the resin R, which is accommodated in the portion of the lower portion of the outflow passage 121b and is positively charged, may be discharged to the outside of the dispensing head 120 through the nozzle 121c in the form of dots. That is, the resin dot RD discharged from the nozzle 121c of the dispensing head 120 may be positively charged.

The rod driving unit 124 may be connected to the upper portion of the rod 123 in the accommodating space 121d. The rod driving unit 124 may drive the rod 123 in the upward and downward directions (+z and –z directions). In an embodiment, the rod driving unit 124 may be a piezoelectric element that contracts or expands depending on voltage applied thereto, but the invention is not limited thereto, and the rod driving unit 124 may be modified in various ways, such as a pneumatic cylinder, or the like.

The resin control electrode 140 may be positioned between the dispensing head 120 and the stage 110. The resin control electrode 140 may be positioned in the upward direction (+z direction) from the stage 110 and in the downward direction (-z direction) from the dispensing head 120. The resin control electrode 140 may control a path of the resin dot RD by adjusting a position of the resin dot RD discharged from the nozzle 121c of the dispensing head 120.

The resin control electrode 140 may include a conductive material, such as a metal or an alloy. In an embodiment, for example, the resin control electrode 140 may include a highly conductive metal, such as copper, but this is merely an example and the invention is not limited thereto. A second voltage having a same polarity as the first voltage may be applied to the resin control electrode 140. In an embodiment, for example, the second voltage may be a positive voltage. In an embodiment, for example, the magnitude of the second voltage may be in a range of about 0.1 kV to about 10 kV, but this is merely an example and the invention is not limited thereto.

In an embodiment, in a plan view, the resin control electrode 140 may have a ring shape in which an opening OP is defined at an inner portion thereof. In an embodiment, for example, as illustrated in FIG. 2, the resin control electrode 140 may have a circular ring shape in a plan view, but this is merely an example and the invention is not limited thereto. In an embodiment, for example, a radius of the opening OP of the resin control electrode 140 may be in a range of about 1 millimeter to about 10 millimeters, a width W of the resin control electrode 140 may be in a range of about 0.1 millimeter to about 1 millimeter, and a thickness T of the resin control electrode 140 may be in a range of about 0.1 millimeter to about 1 millimeter, but this is merely an example and the invention is not limited thereto.

The resin control electrode 140 may be positioned below the dispensing head 120, so that the nozzle 121c of the dispensing head 120 is in (or overlaps) the opening OP of the resin control electrode 140 in a plan view (or in z direction). That is, the resin dot RD discharged from the nozzle 121c of the dispensing head 120 may pass through the opening OP of the resin control electrode 140, and may be landed on the substrate S. At this time, since the resin control electrode 140 is charged with a same polarity as the polarity of the resin dot RD, the resin dot RD may be moved toward a center point 140c of the resin control electrode 140 by a repulsive force RF between the resin dot RD and the resin control electrode 140 (see FIG. 2).

As described below, the resin control electrode 140 may be moved relative to the dispensing head 120 by the electrode moving unit 162. The dispensing apparatus 100 according to an embodiment may control the path of the resin dot RD by appropriately adjusting, in real time, the position of the resin control electrode 140 relative to the dispensing head 120, based on a landing state of the resin dot RD, so that the resin dot RD can land on a target position on the substrate S. In such an embodiment, the smaller the resin dot RD is, the greater the effect of the resin control electrode 140 on controlling the path of the resin dot RD may become.

The head moving unit 161 may be connected to the dispensing head 120, and may be configured to move the dispensing head 120 relative to the stage 110. In an embodiment, while the stage 110 is fixed, the dispensing head 120 may be moved by the head moving unit 161 and discharge the resin dots RD onto the target positions on the substrate S, thereby forming a resin layer RSL of various shapes. The head moving unit 161 may move the dispensing head 120 relative to the stage 110 in the x-axis direction, the y-axis direction, and/or the z-axis direction. In an embodiment, the head moving unit 161 may refer to mechanical components or assemblies that enable the dispensing head 120 to move in various directions or positions, and may include a motor, a pneumatic cylinder or an electric actuator, for example.

The electrode moving unit 162 may be connected to the resin control electrode 140, and may be configured to move the resin control electrode 140. The electrode moving unit 162 may move the resin control electrode 140 in the x-axis direction, the y-axis direction, and/or the z-axis direction. In an embodiment, the electrode moving unit 162 may refer to mechanical components or assemblies that enable the resin control electrode 140 to move in various directions or positions, and may include a motor, a pneumatic cylinder or an electric actuator, for example.

In an embodiment, the resin control electrode 140 may be moved together with the dispensing head 120 when the dispensing head 120 moves. That is, the resin control electrode 140 may be moved together with the dispensing head 120 relative to the stage 110 by the head moving unit 161, and may also be moved relative to the dispensing head 120 by the electrode moving unit 162, simultaneously.

In an embodiment, the dispensing head 120 and the resin control electrode 140 may be moved independently of each other by the head moving unit 161 and the electrode moving unit 162. In an embodiment, the electrode moving unit 162 may move the resin control electrode 140 so that the resin control electrode 140 moves together with the dispensing head 120 when the dispensing head 120 moves. In addition, when correction of the landing position of the resin dot RD is desired, the electrode moving unit 162 may move the resin control electrode 140 so that the resin control electrode 140 also moves relative to the dispensing head 120.

The power supply unit 170 may apply voltages to the components of the dispensing apparatus 100. The power supply unit 170 may include a first power supply unit 171 that applies the first voltage to the head electrode 122 and a second power supply unit 172 that applies the second voltage to the resin control electrode 140. The first power supply unit 171 and the second power supply unit 172 may independently apply the first voltage and the second voltage to the head electrode 122 and the resin control electrode 140, respectively. The first power supply unit 171 and the second power supply unit 172 may be configured as multiple channels of a single power supply device, or may be configured as multiple power supply devices.

The measuring unit 180 may generate measurement data by measuring the landing position of the resin dot RD on the substrate S. In an embodiment, for example, the measuring unit 180 may include a camera. In an embodiment, the measuring unit 180 may obtain images of the substrate S in real time when the dispensing head 120 discharges the resin dot RD, and may generate the measurement data in real time. In an embodiment, the measuring unit 180 may obtain images of the substrate S after the resin dot RD landed on the substrate S is cured, and may generate the measurement data.

The control unit 190 may control the operation of each component of the dispensing apparatus 100. In an embodiment, the control unit 190 may be included in a processor.

In an embodiment, the control unit 190 may receive the measurement data from the measuring unit 180. In an embodiment, the control unit 190 may receive in real time the measurement data generated in real time by the measuring unit 180.

The control unit 190 may control the head moving unit 161 to move the dispensing head 120 relative to the stage 110.

The control unit 190 may control the electrode moving unit 162 to move the resin control electrode 140 relative to the dispensing head 120 based on the measurement data received from the measuring unit 180.

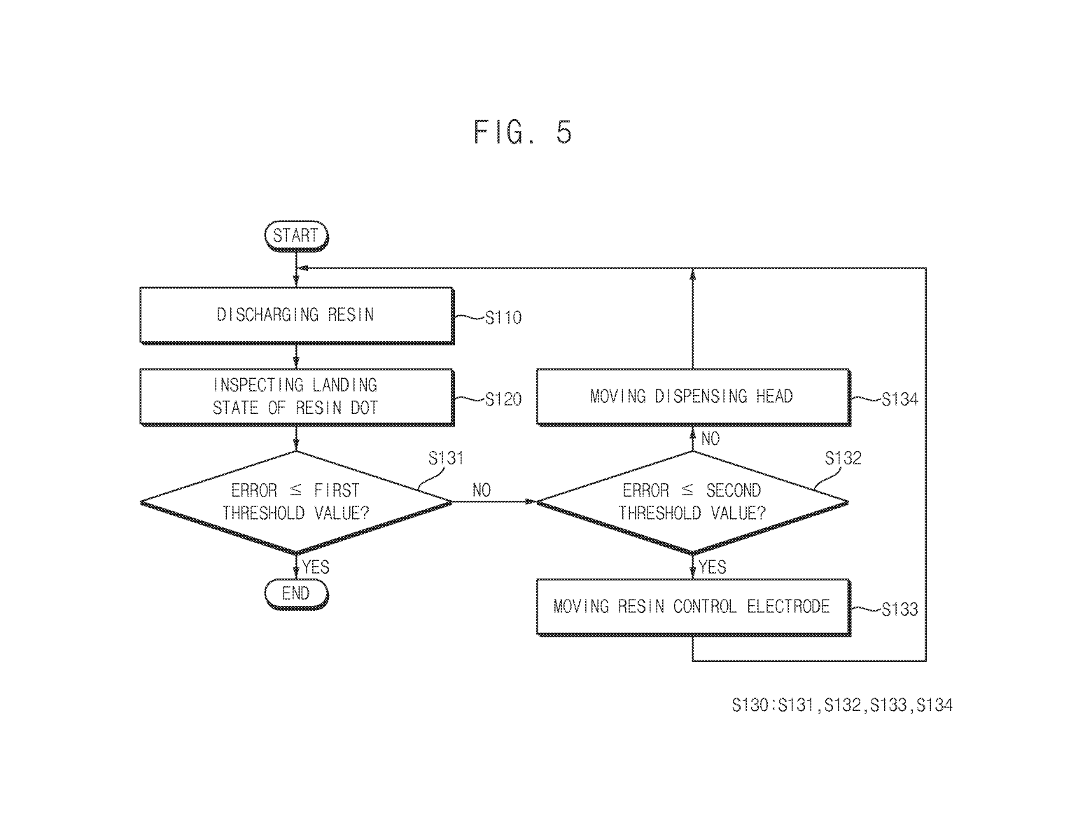

The control unit 190 may receive in real time the measurement data from the measuring unit 180, and may inspect in real time the landing state of the resin dot RD on the substrate S based on the measurement data. In an embodiment, for example, the control unit 190 may inspect the landing state of the resin dot RD by calculating an error between the landing position of the resin dot RD and the target position based on the measurement data. Based on the inspection result of the landing state of the resin dot RD, the control unit 190 may control the head moving unit 161 to adjust the position of the dispensing head 120 relative to the stage 110, or may control the electrode moving unit 162 to adjust the position of the resin control electrode 140 relative to the dispensing head 120. This will be described in detail later with reference to FIG. 5.

In an embodiment, the control unit 190 may control the power supply unit 170 to adjust the magnitude of the first voltage and/or the magnitude of the second voltage based on the inspection result of the landing state of the resin dot RD.

According to the dispensing apparatus 100 according to embodiments, the charged resin R may be discharged from the nozzle 121c of the dispensing head 120 in the form of dots. The discharged resin dot RD may pass through the opening OP of the resin control electrode 140, which is charged with a same polarity as the polarity of the charged resin R (i.e., the resin dot RD), and may be landed on the substrate S. The control unit 190 may inspect in real time the landing state of the resin dot RD on the substrate S, and may control in real time the path of the resin dot RD discharged from the nozzle 121c based on the inspection result. In an embodiment, for example, the control unit 190 may control in real time the path of the resin dot RD, by adjusting in real time the position of the resin control electrode 140 relative to the dispensing head 120, based on the inspection result, so that the resin dot RD may land on the target position on the substrate S. Accordingly, even when the resin dot RD is discharged from the nozzle 121c in an oblique direction due to nozzle clogging, increased moving speed of the dispensing head 120, or the like, the dispensing apparatus 100 may control in real time the path of the resin dot RD so that the resin dot RD may land on the target position on the substrate S. Accordingly, the discharge accuracy of the dispensing apparatus 100 may be improved.

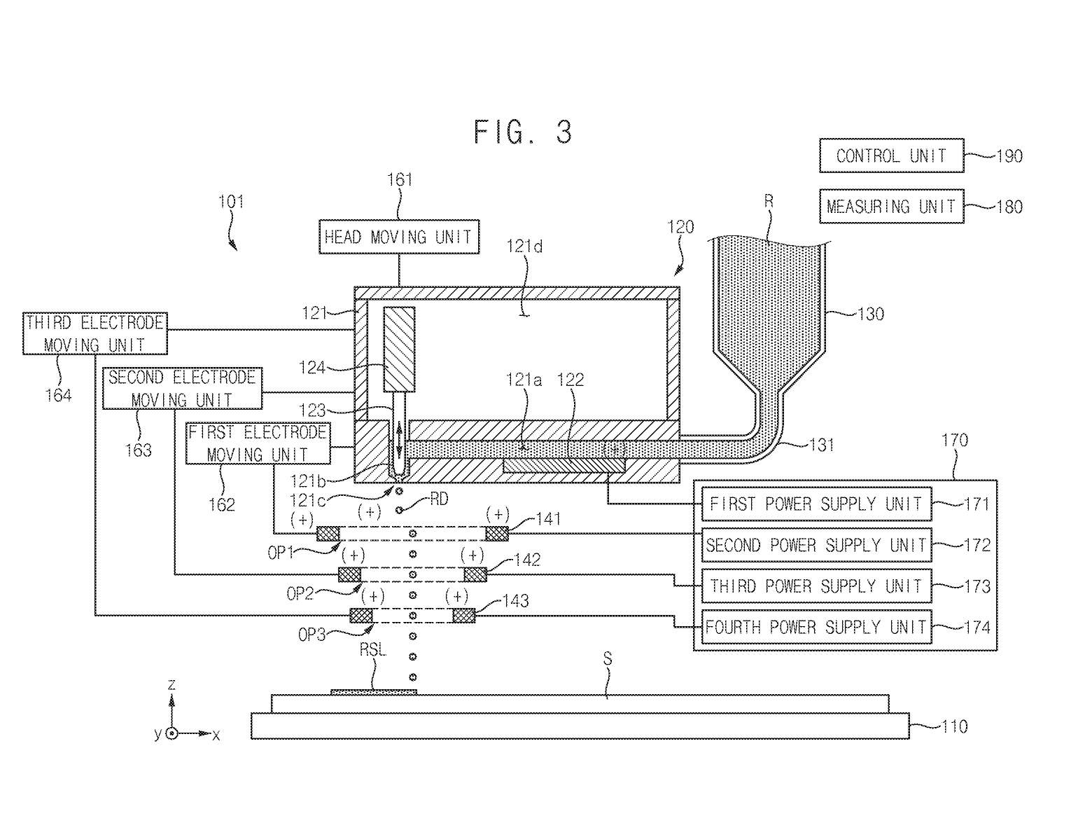

FIG. 3 is a schematic diagram illustrating a dispensing apparatus according to an embodiment.

An embodiment of the dispensing apparatus 101 described below with reference to FIG. 3 may be substantially the same as or similar to the embodiment of the dispensing apparatus 100 described above with reference to FIG. 1, except that the resin control electrode 140 of FIG. 1 are provided in plurality. Therefore, any repetitive detailed description of the same or like elements as those described above will be omitted or simplified.

Referring to FIG. 3, in an embodiment, the dispensing apparatus 101 may include the stage 110, the dispensing head 120, the resin supply unit 130, a first resin control electrode 141, a second resin control electrode 142, a third resin control electrode 143, the head moving unit 161, a first electrode moving unit 162, a second electrode moving unit 163, a third electrode moving unit 164, the power supply unit 170, the measuring unit 180, and the control unit 190.

The dispensing head 120 may electrically charge the resin R, which is supplied from the resin supply unit 130, and may discharge the charged resin R through the nozzle 121c in the form of dots.

The first resin control electrode 141 may be positioned in the downward direction (-z direction) from the dispensing head 120. The second resin control electrode 142 may be positioned in the downward direction (-z direction) from the first resin control electrode 141. The third resin control electrode 143 may be positioned in the upward direction (+z direction) from the stage 110 and in the downward direction (-z direction) from the second resin control electrode 142.

The first to third resin control electrodes 141, 142, and 143 may control the path of the resin dot RD by adjusting the position of the resin dot RD discharged from the nozzle 121c of the dispensing head 120. FIG. 3 illustrates an embodiment where the dispensing apparatus 101 includes three resin control electrodes, but the number of resin control electrodes may be variously changed, for example, two or four or more.

Each of the first to third resin control electrodes 141, 142, and 143 may include a conductive material, such as a metal or an alloy. In an embodiment, for example, each of the first to third resin control electrodes 141, 142, and 143 may include a highly conductive metal, such as copper, but this is merely an example and the invention is not limited thereto.

The second voltage having a same polarity as the first voltage, which is applied to the head electrode 122, may be applied to the first resin control electrode 141. A third voltage having the same polarity as the first voltage may be applied to the second resin control electrode 142. A fourth voltage having the same polarity as the first voltage may be applied to the third resin control electrode 143. In an embodiment, for example, each of the first to fourth voltages may be a positive voltage.

In an embodiment, the magnitudes of the second to fourth voltages may be different from each other. In an embodiment, for example, the magnitude of the third voltage may be less than the magnitude of the second voltage, and the magnitude of the fourth voltage may be less than the magnitude of the third voltage. In another embodiment, the magnitudes of the second to fourth voltages may be equal to each other.

In an embodiment, in a plan view, each of the first to third resin control electrodes 141, 142, and 143 may have a ring shape in which an opening is defined at an inner portion thereof. In a plan view, the first resin control electrode 141 may have a circular ring shape in which a first opening OP1 is defined at an inner portion thereof. In a plan view, the second resin control electrode 142 may have a circular ring shape in which a second opening OP2 is defined at an inner portion thereof. In a plan view, the third resin control electrode 143 may have a circular ring shape in which a third opening OP3 is defined at an inner portion thereof. In an embodiment, for example, the first to third resin control electrodes 141, 142, and 143 may have substantially the same width and substantially the same thickness as each other, but the invention is not limited thereto.

In an embodiment, in a plan view, sizes of the first to third openings OP1, OP2, and OP3 may be different from each other. In an embodiment, for example, in a plan view, the size of the second opening OP2 may be less than the size of the first opening OP1, and the size of the third opening OP3 may be less than the size of the second opening OP2. In another embodiment, in a plan view, the sizes of the first to third openings OP1, OP2, and OP3 may be equal to each other.

The resin dot RD discharged from the nozzle 121c of the dispensing head 120 may sequentially pass through the first opening OP1 of the first resin control electrode 141, the second opening OP2 of the second resin control electrode 142, and the third opening OP3 of the third resin control electrode 143, and may be landed on the substrate S. At this time, since each of the first to third resin control electrodes 141, 142, and 143 is charged with the same polarity as the polarity of the resin dot RD, the resin dot RD may be moved toward a center point of each of the first to third resin control electrodes 141, 142, and 143 by a repulsive force between the resin dot RD and each of the first to third resin control electrodes 141, 142, and 143.

The head moving unit 161 may be connected to the dispensing head 120, and may be configured to move the dispensing head 120 relative to the stage 110. In an embodiment, while the stage 110 is fixed, the dispensing head 120 may be moved by the head moving unit 161 and discharge the resin dots RD onto the target positions on the substrate S, thereby forming a resin layer RSL of various shapes.

The first electrode moving unit 162 may be connected to the first resin control electrode 141, and may be configured to move the first resin control electrode 141. The first electrode moving unit 162 may move the first resin control electrode 141 in the x-axis direction, the y-axis direction, and/or the z-axis direction.

The second electrode moving unit 163 may be connected to the second resin control electrode 142, and may be configured to move the second resin control electrode 142. The second electrode moving unit 163 may move the second resin control electrode 142 in the x-axis direction, the y-axis direction, and/or the z-axis direction.

The third electrode moving unit 164 may be connected to the third resin control electrode 143, and may be configured to move the third resin control electrode 143. The third electrode moving unit 164 may move the third resin control electrode 143 in the x-axis direction, the y-axis direction, and/or the z-axis direction.

In an embodiment, the first to third electrode moving units 162, 163, and 164 may be configured to independently move the first to third resin control electrodes 141, 142, and 143, respectively.

In an embodiment, the first to third resin control electrodes 141, 142, and 143 may be moved together with the dispensing head 120 when the dispensing head 120 moves. That is, the first to third resin control electrodes 141, 142, and 143 may be moved together with the dispensing head 120 relative to the stage 110 by the head moving unit 161, and may also be moved relative to the dispensing head 120 by the first to third electrode moving units 162, 163, and 164, simultaneously.

In an embodiment, the dispensing head 120 and the first to third resin control electrodes 141, 142, and 143 may be moved independently of each other by the head moving unit 161 and the first to third electrode moving units 162, 163, and 164. In an embodiment, the first to third electrode moving units 162, 163, and 164 may move the first to third resin control electrodes 141, 142, and 143 so that the first to third resin control electrodes 141, 142, and 143 moves together with the dispensing head 120 when the dispensing head 120 moves. In addition, when correction of the landing position of the resin dot RD is desired, the first to third electrode moving units 162, 163, and 164 may move the first to third resin control electrodes 141, 142, and 143 so that the first to third resin control electrodes 141, 142, and 143 also moves relative to the dispensing head 120.

The power supply unit 170 may apply voltages to the components of the dispensing apparatus 101. The power supply unit 170 may include the first power supply unit 171 that applies the first voltage to the head electrode 122, the second power supply unit 172 that applies the second voltage to the first resin control electrode 141, the third power supply unit 173 that applies the third voltage to the second resin control electrode 142, and the fourth power supply unit 174 that applies the fourth voltage to the third resin control electrode 143. The first to fourth power supply units 171, 172, 173, and 174 may independently apply the first to fourth voltages to the head electrode 122 and the first to third resin control electrodes 141, 142, and 143, respectively. The first to fourth power supply units 171, 172, 173, and 174 may be configured as multiple channels of a single power supply device, or may be configured as multiple power supply devices.

The measuring unit 180 may generate the measurement data by measuring the landing position of the resin dot RD on the substrate S.

The control unit 190 may control the operation of each component of the dispensing apparatus 101. In an embodiment, the control unit 190 may receive in real time the measurement data generated in real time by the measuring unit 180.

The control unit 190 may receive in real time the measurement data from the measuring unit 180, and may inspect in real time the landing state of the resin dot RD on the substrate S based on the measurement data. In an embodiment, for example, the control unit 190 may inspect the landing state of the resin dot RD by calculating an error between the landing position of the resin dot RD and the target position based on the measurement data. Based on the inspection result of the landing state of the resin dot RD, the control unit 190 may control the head moving unit 161 to adjust the position of the dispensing head 120 relative to the stage 110, or may control the first to third electrode moving units 162, 163, and 164 to adjust the position of the first to third resin control electrodes 141, 142, and 143 relative to the dispensing head 120.

According to an embodiment, as described above, the dispensing apparatus 101 may include the plurality of resin control electrodes 141, 142, and 143 arranged along the discharge path of the resin dot RD discharged from the nozzle 121c of the dispensing head 120. Accordingly, the path of the resin dot RD may be controlled more precisely. Therefore, the application discharge accuracy of the dispensing apparatus 101 may be further improved.

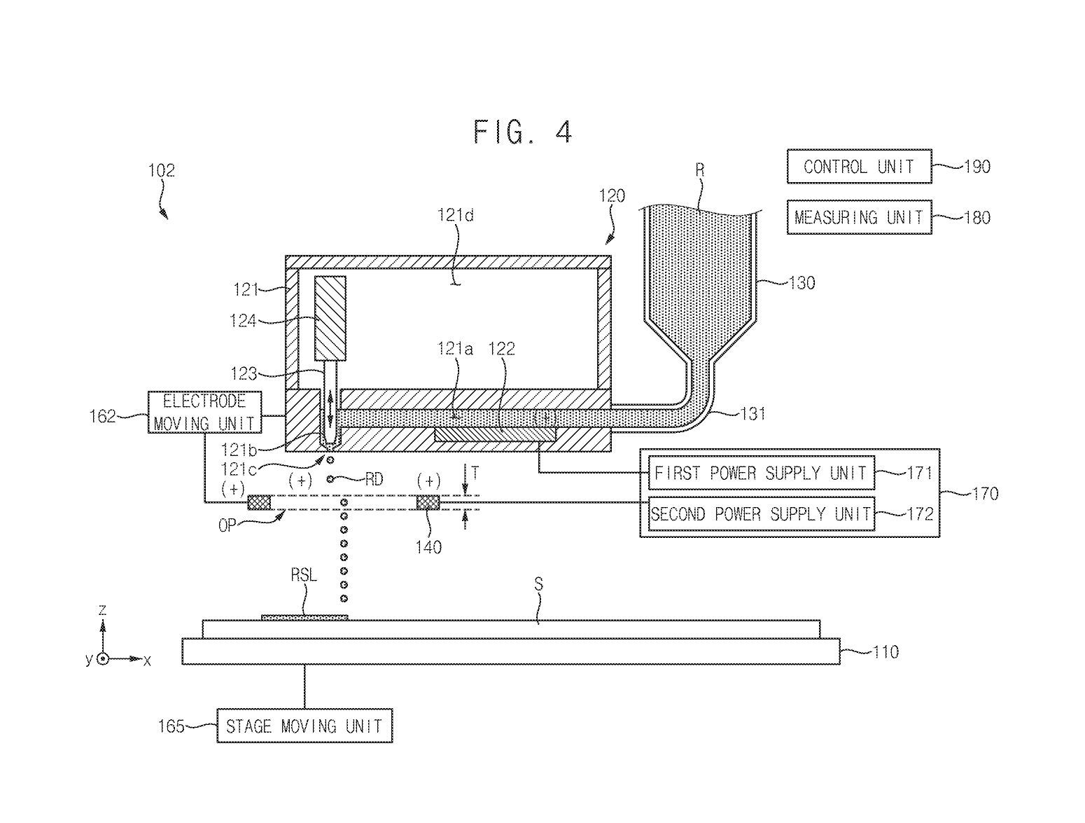

FIG. 4 is a schematic diagram illustrating a dispensing apparatus according to an embodiment.

An embodiment of the dispensing apparatus 102 described below with reference to FIG. 4 may be substantially the same as or similar to the embodiments of the dispensing apparatus 100 described above with reference to FIG. 1, except that the head moving unit 161 of FIG. 1 is omitted and the stage moving unit 165 is further included. Therefore, any repetitive detailed description of the same or like elements as those described above will be omitted or simplified.

In an embodiment, the dispensing head 120 may electrically charge the resin R, which is supplied from the resin supply unit 130, and may discharge the charged resin R through the nozzle 121c in the form of dots.

The resin control electrode 140 may be positioned between the dispensing head 120 and the stage 110. The resin control electrode 140 may control the path of the resin dot RD by adjusting the position of the resin dot RD discharged from the nozzle 121c of the dispensing head 120.

The electrode moving unit 162 may be connected to the resin control electrode 140, and may be configured to move the resin control electrode 140 relative to the dispensing head 120. The electrode moving unit 162 may move the resin control electrode 140 in the x-axis direction, the y-axis direction, and/or the z-axis direction.

The stage moving unit 165 may be connected to the stage 110, and may be configured to move the stage 110 relative to the dispensing head 120. In an embodiment, while the dispensing head 120 is fixed and discharges the resin dots RD in the downward direction (-z direction), the stage 110 on which the substrates S is seated may be moved by the stage moving unit 165, and the resin dots RD may be land onto the target positions on the substrate S, thereby forming a resin layer RSL of various shapes. The stage moving unit 165 may move the stage 110 in the x-axis direction, the y-axis direction, and/or the z-axis direction. In an embodiment, the stage moving unit 165 may refer to mechanical components or assemblies that enable the stage 110 to move in various directions or positions, and may include a motor, a pneumatic cylinder or an electric actuator, for example.

FIG. 5 is a flowchart illustrating a dispensing method according to an embodiment.

A dispensing method of FIG. 5 may be a dispensing method performed using an embodiment of the dispensing apparatus 100, 101, or 102 described above with reference to FIGS. 1 to 3. Hereinafter, for convenience of description, the dispensing method according to an embodiment will be described with further reference to FIG. 1.

In an embodiment of a dispensing method, the dispensing head 120 may discharge the resin R through the nozzle 121c onto the substrate S in the form of dots (S110). The resin R supplied from the resin supply unit 130 may be continuously discharged toward the substrate S by the dispensing head 120 in the form of fine dots.

Before the discharging the resin R onto the substrate S (S110), the resin R may be electrically charged inside the dispensing head 120. The first voltage may be applied to the head electrode 122, which is adjacent to the inflow passage 121a of the dispensing head 120, to electrically charge the resin R passing through the inflow passage 121a. In an embodiment, for example, the first voltage may be a positive voltage. The resin R passing through the inflow passage 121a may be positively charged by the head electrode 122. Accordingly, the positively charged resin R may be discharged outside the dispensing head 120 through the nozzle 121c of the dispensing head 120 in the form of dots. That is, the resin dot RD discharged from the nozzle 121c of the dispensing head 120 may be positively charged.

The control unit 190 may inspect the landing state of the resin R (i.e., the resin dot RD) on the substrate S (S120).

In an embodiment, before the inspecting the landing state of the resin R (S120), the measurement data may be generated by measuring the landing position of the resin R (i.e., the resin dot RD) on the substrate S. The measuring unit 180 may generate the measurement data by measuring the landing position of the resin dot RD on the substrate S. The measuring unit 180 may obtain the images of the substrate S in real time when the dispensing head 120 discharges the resin dot RD, and may generate the measurement data in real time.

The control unit 190 may receive in real time the measurement data generated in real time by the measuring unit 180. The control unit 190 may inspect in real time the landing state of the resin dot RD on the substrate S based on the measurement data received from the measuring unit 180 (S120). The control unit 190 may inspect the landing state of the resin dot RD by calculating the error between the landing position of the resin dot RD and the target position based on the measurement data.

The control unit 190 may control the landing position of the resin R (i.e., the resin dot RD) based on the inspection result of the landing state (S130). Based on the inspection result of the landing state, the control unit 190 may control the head moving unit 161 to adjust the position of the dispensing head 120 relative to the stage 110, or may control the electrode moving unit 162 to adjust the position of the resin control electrode 140 relative to the dispensing head 120, so that the landing position of the resin R (i.e., the resin dot RD) on the substrate S may be controlled.

In an embodiment, the control unit 190 may determine whether the error is less than or equal to a first threshold value (S131). If the error is less than or equal to the first threshold value (S131:YES), the control unit 190 may determine that the landing state of the resin R is normal. If the error is greater than the first threshold value (S131:NO), the control unit 190 may determine whether the error is less than or equal to a second threshold value, which is greater than the first threshold value (S132).

In an embodiment, if the error is greater than the first threshold value and is less than or equal to the second threshold value (S132:YES), the electrode moving unit 162 may move the resin control electrode 140 to adjust the position of the resin control electrode 140 relative to the dispensing head 120 (S133). If the error is greater than the first threshold value and is less than or equal to the second threshold value (S132:YES), the control unit 190 may control the electrode moving unit 162 to move the resin control electrode 140 relative to the dispensing head 120.

In an embodiment, if the error is greater than the second threshold value (S132:NO), the head moving unit 161 may move the dispensing head 120 to adjust the position of the dispensing head 120 relative to the stage 110 (S134). If the error is greater than the second threshold value (S132:NO), the control unit 190 may control the head moving unit 161 to move the dispensing head 120 relative to the stage 110. At this time, the resin control electrode 140 may be moved together with the dispensing head 120 when the dispensing head 120 moves.

In an embodiment, for example, the first threshold value may be 20 micrometers and the second threshold value may be 50 micrometers, but this is merely an example and the invention is not limited thereto.

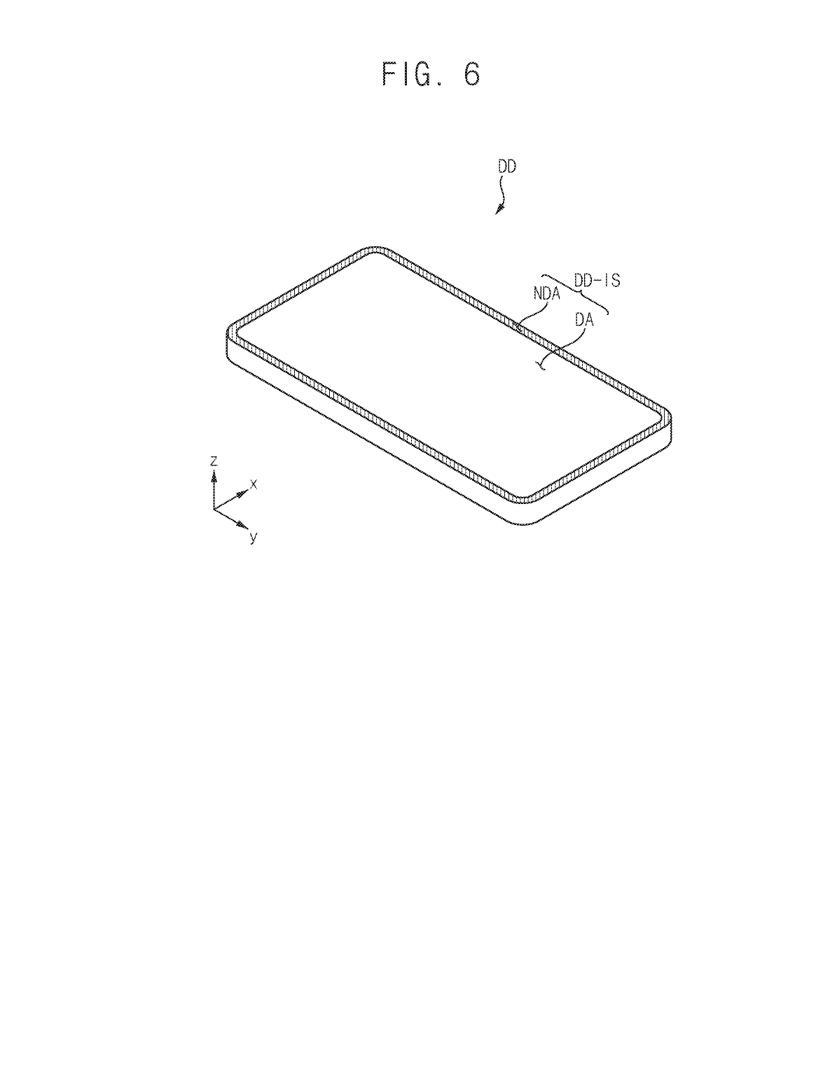

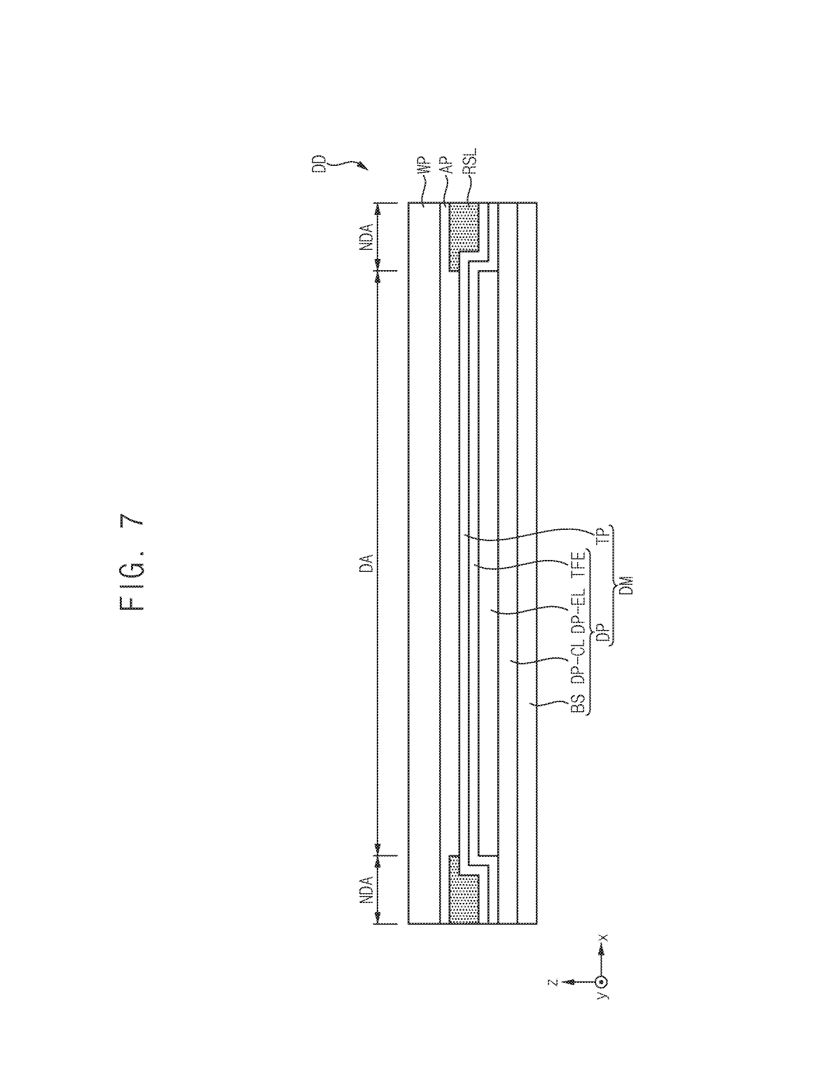

FIG. 6 is a perspective view illustrating a display device according to an embodiment. FIG. 7 is a cross-sectional view of the display device of FIG. 6.

Referring to FIGS. 6 and 7, a display device DD according to an embodiment may display an image through a display surface DD-IS.

In an embodiment, the display device DD may include a display area DA that displays an image and a non-display area NDA that does not display an image. In an embodiment, the non-display area NDA may at least partially surround the display area DA in a plan view. However, the invention is not limited thereto, and the non-display area NDA may be omitted.

In an embodiment, as shown in FIG. 7, the display device DD may include a display module DM, a window WP, and an adhesive member AP.

The display module DM may include a display panel DP and an input sensing layer TP.

The display panel DP may include a plurality of pixels for generating the image. Each of the pixels may include a pixel circuit and a light emitting element. The pixel circuit may include at least one thin film transistor and at least one capacitor. The pixel circuit may generate a driving current, and may provide the generated driving current to the light emitting element. The light emitting element may emit light based on the driving current. In an embodiment, for example, the light emitting element may include an organic light emitting diode, an inorganic light emitting diode, a quantum dot light emitting diode, a micro light emitting diode, or the like. The image may be generated by combining the light emitted by each of the pixels.

In an embodiment, the display panel DP may include a base substrate BS, a circuit layer DP-CL, a light emitting element layer DP-EL, and an encapsulation layer TFE.

The base substrate BS may form a base (or provide a base surface) of the display panel DP. The base substrate BS may be an insulating substrate including or formed of a transparent or opaque material. The base substrate BS may be flexible or rigid.

The circuit layer DP-CL may be disposed on the base substrate BS. The circuit layer DP-CL may include the pixel circuit and a plurality of insulating layers.

The light emitting element layer DP-EL may be disposed on the circuit layer DP-CL. The light emitting element layer DP-EL may include the light emitting element. The light emitting element in the light emitting element layer DP-EL may be electrically connected to the corresponding pixel circuit in the circuit layer DP-CL.

The encapsulation layer TFE may be disposed on the light emitting element layer DP-EL. The encapsulation layer TFE may cover the light emitting element layer DP-EL. The encapsulation layer DP-EL may effectively prevent or substantially reduce penetration of impurities, such as oxygen, moisture, or the like, into the light emitting element layer DP-EL. In an embodiment, for example, the encapsulation layer TFE may include at least one inorganic encapsulation layer and at least one organic encapsulation layer.

The input sensing layer TP may be disposed on the encapsulation layer TFE. In an embodiment, for example, the input sensing layer TP may be disposed directly on the encapsulation layer TFE. The input sensing layer TP may detect an external input, change the detected external input to a predetermined input signal, and provide the input signal to the display panel DP. In an embodiment, for example, the input sensing layer TP may be a touch sensing layer which detects a touch. The input sensing layer TP may recognize a direct touch by a user, an indirect touch by a user, a direct touch by an object, an indirect touch by an object, or the like.

The window WP may be disposed on the input sensing layer TP. The window WP may define an upper surface (or a front surface) of the display device DD. The window WP may have light transmitting characteristics. In an embodiment, for example, the window WP may include a resin film, such as polyimide, or the like, or ultra-thin glass (”UTG”).

The adhesive member AP may be disposed between the display module DM and the window WP. The adhesive member AP may attach the window WP to the display module DM. The adhesive member AP may have light transmitting characteristics. In an embodiment, for example, the adhesive member AP may include an optical clear adhesive (“OCA”), a pressure sensitive adhesive (“PSA”), or the like.

In an embodiment, the display device DD may include a resin layer RSL, which is disposed in the non-display area NDA on the display module DM and includes resin. The resin layer RSL may be a layer that performs various functions, such as improving the strength of the non-display area NDA of the display device DD, preventing moisture penetration from the outside, preventing light leakage from the side of the display device DD, or the like.

In an embodiment, the resin layer RSL of the display device DD may be formed using the dispensing apparatus 100, 101, and 102 described above with reference to FIGS. 1 to 4. In such an embodiment, the display module DM including the display panel DP may be the substrate S of FIGS. 1 to 4. However, this is merely an example and the invention is not limited thereto, and the dispensing apparatus of the invention may be used not only to form the resin layer RSL disposed in the non-display area NDA of the display device DD, but also to form resin patterns or resin layers desired to be formed with fine dispensing in various electronic devices.

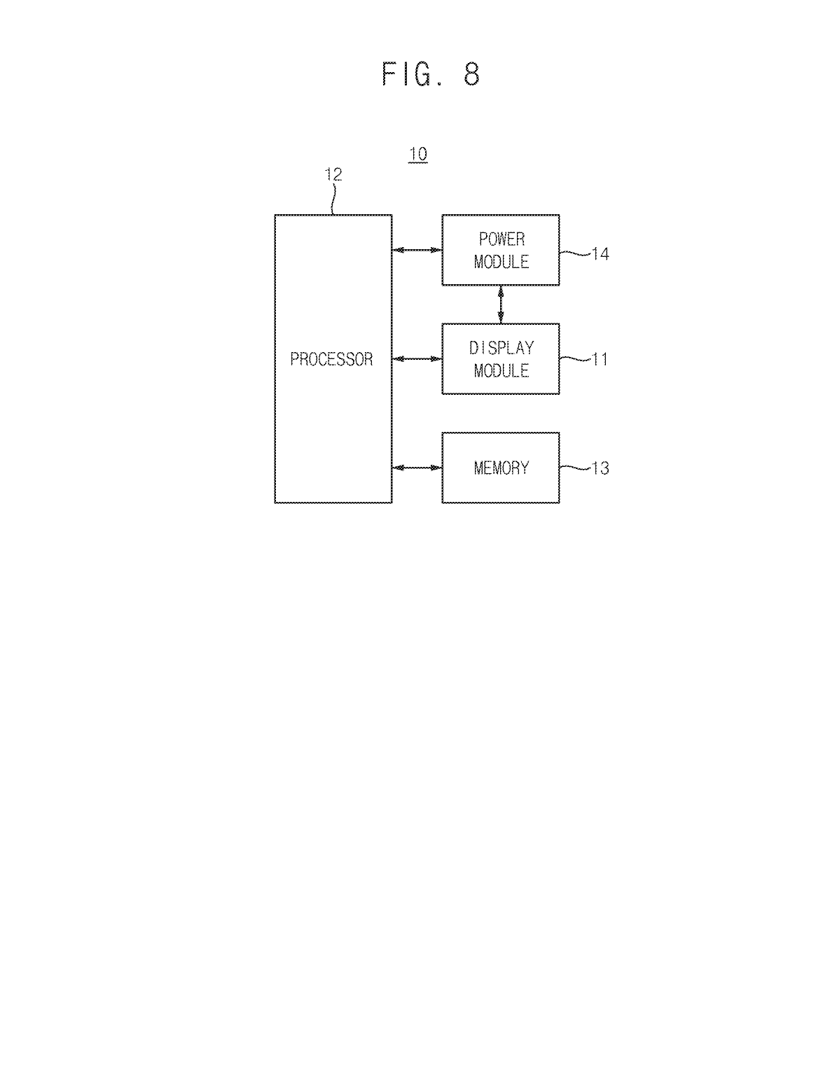

FIG. 8 is a block diagram illustrating an electronic device according to an embodiment.

Referring to FIG. 8, an embodiment of an electronic device 10 may include a display module 11, a processor 12, a memory 13, and a power module 14.

A display device according to embodiments (e.g., the display device DD of FIGS. 6 and 7) may be applied to or included in various electronic devices 10. The electronic device 10 may include the display device described above, and may further include modules or devices with additional functions other than the display device.

The processor 12 may include at least one selected from a central processing unit (“CPU”), an application processor (“AP”), a graphic processing unit (“GPU”), a communication processor (“CP”), an image signal processor (“ISP”), and a controller.

The memory 15 may store data information used for the operation of the processor 12 or the display module 11. When the processor 12 executes the application stored in the memory 15, an image data signal and/or an input control signal may be transmitted to the display module 11, and the display module 11 may process the received signal and output image information through a display screen.

The power module 14 may include a power supply module, such as a power adapter or a battery device, and a power conversion module which converts the power supplied by the power supply module to generate power for the operation of the electronic device 10.

At least one of each component of the electronic device 10 described above may be included in the display device according to embodiments. In addition, some of the individual modules functionally included in one module may be included in the display device, and other portions may be provided separately from the display device. In an embodiment, for example, the display device may include the display module 11, and the processor 12, the memory 13, and the power module 14 may be provided in the form of other devices within the electronic device 10 other than the display device.

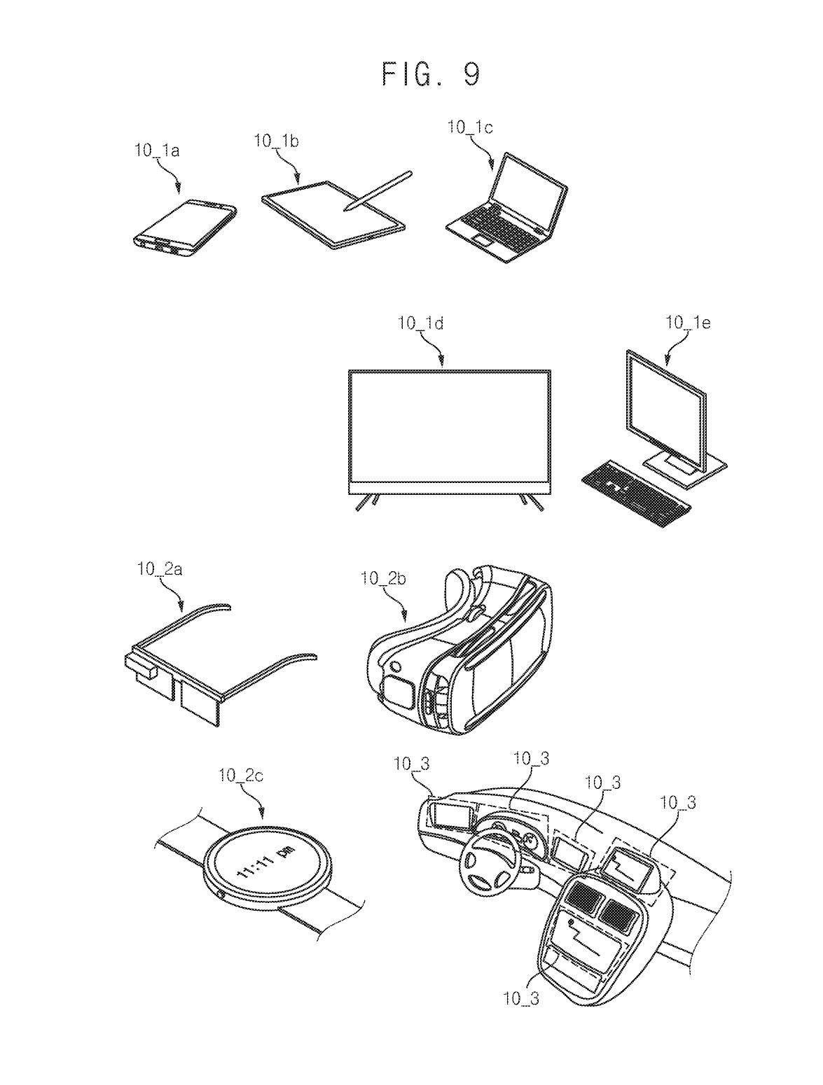

FIG. 9 is a schematic diagram illustrating an electronic device according to various embodiments.

Referring to FIG. 9, various electronic devices 10 to which the display device according to embodiments are applied may include not only image display electronic devices such as a smartphone 10_1a, a tablet personal computer (“PC”) 10_1b, a laptop 10_1c, a television (“TV”) 10_1d, and a desktop monitor 10_1e, but also wearable electronic devices including display modules, such as smart glasses 10_2a, a head-mounted display 10_2b, and a smart watch 10_2c, automotive electronic devices 10_3 including display modules, such as a dashboard of a car, a center fascia, a center information display (“CID”) disposed on a dashboard, and a room mirror display, or the like.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A dispensing apparatus comprising:
a stage, on which a substrate is seated;
a dispensing head positioned above the stage, wherein the dispensing head includes a head electrode, to which a first voltage is applied to electrically charge a resin, and the dispensing head discharges a charged resin through a nozzle thereof onto the substrate in the form of dots; and
a resin control electrode positioned between the dispensing head and the stage, wherein a second voltage having a same polarity as the first voltage is applied to the resin control electrode to control a position of a resin dot discharged from the nozzle.

2. The dispensing apparatus of claim 1, wherein in a plan view, the resin control electrode has a ring shape in which an opening is defined at an inner portion thereof.

3. The dispensing apparatus of claim 2, wherein the resin dot discharged from the nozzle of the dispensing head passes through the opening of the resin control electrode and is landed on the substrate.

4. The dispensing apparatus of claim 1, further comprising:
an electrode moving unit which moves the resin control electrode.

5. The dispensing apparatus of claim 4, further comprising:
a measuring unit which measures the position of the resin dot landed on the substrate; and
a control unit which controls the electrode moving unit to adjust, in real time, a position of the resin control electrode relative to the dispensing head based on a measurement data received from the measuring unit.

6. The dispensing apparatus of claim 4, further comprising:
a head moving unit which moves the dispensing head relative to the stage.

7. The dispensing apparatus of claim 6, wherein the resin control electrode moves together with the dispensing head when the dispensing head moves.

8. The dispensing apparatus of claim 4, further comprising:
a stage moving unit which moves the stage relative to the dispensing head.

9. The dispensing apparatus of claim 1, wherein the resin control electrode is provided in plurality, and
a plurality of resin control electrodes include:
a first resin control electrode positioned below the dispensing head, wherein the second voltage is applied to the first resin control electrode; and
a second resin control electrode positioned below the first resin control electrode, wherein a third voltage having the same polarity as the first voltage is applied to the second resin control electrode.

10. The dispensing apparatus of claim 9, wherein in a plan view, each of the first resin control electrode and the second resin control electrode has a ring shape in which an opening is defined at an inner portion thereof, and
wherein a size of the opening defined in the second resin control electrode is less than a size of the opening defined in the first resin control electrode.

11. The dispensing apparatus of claim 9, wherein a magnitude of the second voltage is different from a magnitude of the third voltage.

12. The dispensing apparatus of claim 9, further comprising:
a first electrode moving unit which moves the first resin control electrode; and
a second electrode moving unit which moves the second resin control electrode.

13. The dispensing apparatus of claim 1, wherein the dispensing head further includes a plate which forms a main body of the dispensing head and defines an outflow passage extending upward from the nozzle and an inflow passage communicating with the outflow passage, wherein the resin is introduced into the dispensing head through the inflow passage from a resin supply unit, and
wherein the head electrode is close to the inflow passage.

14. The dispensing apparatus of claim 13, wherein the head electrode directly contacts the resin in the inflow passage.

15. The dispensing apparatus of claim 1, wherein each of the first voltage and the second voltage is a positive voltage.

16. A dispensing method comprising:
electrically charging a resin passing through an inflow passage of a dispensing head;
discharging a charged resin through a nozzle of the dispensing head onto a substrate in the form of dots; and
controlling a landing position of a resin dot on the substrate, by adjusting a position of the dispensing head relative to a stage, on which the substrate is seated, or by adjusting a position of a resin control electrode, which is positioned between the dispensing head and the stage and is electrically charged with a same polarity as the charged resin, relative to the dispensing head.

17. The method of claim 16, further comprising:
before the controlling the landing position of the resin dot, generating measurement data by measuring the landing position of the resin dot on the substrate,
wherein in the controlling the landing position of the resin dot, the position of the resin control electrode relative to the dispensing head is adjusted in real time based on the measurement data.

18. The method of claim 17, further comprising:
after the generating the measurement data, inspecting a landing state of the resin dot on the substrate by calculating an error between the landing position of the resin dot and a target position based on the measurement data,
wherein the controlling the landing position of the resin dot includes:
determining that resin dot is normally landed when the error is equal to or less than a first threshold value;
adjusting a position of the resin control electrode relative to the dispensing head by moving the resin control electrode when the error is greater than the first threshold value and is equal to or less than a second threshold value; and
adjusting a position of the dispensing head relative to the stage by moving the dispensing head or the stage when the error is greater than the second threshold value.

19. The method of claim 18, wherein the resin control electrode moves together with the dispensing head when the dispensing head moves.

20. An electronic device comprising:
a display device including a display panel which displays an image and a resin layer disposed on the display panel and formed by a dispensing apparatus; and
a processor which provides an image data signal and an input control signal to the display device,
wherein the dispensing apparatus includes:
a stage on which a substrate is seated;
a dispensing head positioned above the stage, wherein the dispensing head includes a head electrode, to which a first voltage is applied to electrically charge a resin, and the dispensing head discharges a charged resin through a nozzle thereof onto the substrate in the form of dots; and
a resin control electrode positioned between the dispensing head and the stage, wherein a second voltage having a same polarity as the first voltage is applied to the resin control electrode to control a position of a resin dot discharged from the nozzle.
